(19) United States
(12) Patent Application Publication
(10) Pub. No.: US 2007/0233542 A1
(43) Pub. Date: Oct. 4, 2007

(54) Method and system for designing, executing and managing road construction projects

(75) Inventors: Bruno Dubreuil, Rock-Forest (CA); Daniel Lemire, Magog (CA); Nicolas Inkel, Lac Megantic (CA); David Deschenes, Saint-Hubert (CA); Michel Tousignant, Rock-Forest (CA); David Deschenes, (US)

Correspondence Address: BIRCH STEWART KOLASCH & BIRCH, PO BOX 747, FALLS CHURCH, VA, 22040-0747, US

(73) Assignee: CONCEPTION DESIGN WARE, INC., Sherbrooke (CA)

(21) Appl. No.: 11/396,539

(22) Filed: Apr. 4, 2006

(51) Int. Cl. G06F 17/50; E01F 9/00

(52) U.S. Cl. 705/8; 404/9; 705/7

(57) ABSTRACT

In a method and system for executing and managing a road construction project, the following operations are implemented in a single computer software. Input data are defined to provide guidelines for designing the road construction project. Underground layers are determined based on the input data and a plurality of road design scenarios are generated using the underground layers. An optimal road design scenario is selected out of the plurality of scenarios and drawings and specifications are produced to implement the selected optimal road design scenario. Quantities executed during the road construction project are calculated in order to monitor in real time the executed quantities and keep track of the progress in the execution of the road construction project.

### FIELD OF THE INVENTION

The present invention generally relates to road construction. More specifically, the present invention is concerned with a method and system for designing, executing and managing road construction projects.

### BACKGROUND OF THE INVENTION

Existing methods and systems for designing, executing and managing construction projects generally present the following drawbacks:
they generally require a number of different softwares for data acquisition, translation, parameter tables setting, and complementary utilities;
the same information needs to be entered several times in different programs, which can cause a loss and/or degradation of the information;
the technicians, operators and engineers have to learn several softwares in order to design a road project; and
these softwares are expensive.

Also, the majority of the softwares currently available on the market are based on traditional CAD software like AutoCad or Microstation. These softwares generate straight or curved segments, each of which has its own characteristics and properties. It is often possible to put together a set of such segments to create an object. However, the properties of the object are the sum, or the resultant of the properties of every individual segment. When a road is built, the road layout is given by the combination of these segments, because to define a road project, it is necessary to use, couple, and join a series of segments, as well as to give them a length, a direction, a slope, etc. Modifying one property of one of these segments, for example the length, is not necessarily reflected over all the other elements of the outline. Therefore, the designer must check and edit manually each property of each segment. If the designer neglects or forgets to make the modification of the specific property, an error is generated during the layout producing process.

As outlined hereinabove, one drawback of the current methods and systems for designing, executing and managing road construction projects resides in the use of a series of softwares. Not only does this lead to the need of learning several softwares but also this results in compatibility problems between softwares. Indeed, since the series of softwares are programmed by different companies, which do not necessarily communicate with each other, there is more or less harmony between softwares. Often, this lack of harmony and communication leads to the need of acquiring the same information more than once. Furthermore, some of these softwares are so complex that technicians specialized with these softwares are needed. Most of the engineers do not have time to learn a specialized software, which generally demands a long training period and some continuous practice. So not only must they rely on their technicians but also some additional reports are requested to check and validate the project. Finally, one must buy and maintain several licences for several softwares. And the managers can lose track of the progress in the execution of the road construction project. For example, the managers realize only after the project has been completed that the cost for the execution of the project has been exceeded.

### OBJECT OF THE INVENTION

An object of the present invention is therefore to provide a method and system for designing, executing and managing road construction projects that overcome the above discussed drawbacks of the existing methods and systems.

### SUMMARY OF THE INVENTION

More specifically, in accordance with the present invention, there is provided a method for executing and managing a road construction project, comprising the following operations implemented in a single computer software: defining input data providing guidelines for designing the road construction project; determining underground layers based on the input data; generating a plurality of road design scenarios using the underground layers; selecting an optimal road design scenario out of the plurality of scenarios; producing drawings and specifications to implement the selected optimal road design scenario; and calculating quantities executed during the road construction project in order to monitor in real time the executed quantities and keep track of the progress in the execution of the road construction project.

The present invention also relates to a system for executing and managing a road construction project, comprising, implemented in a single computer software: a definer of input data providing guidelines for designing the road construction project; a generator of underground layers based on the input data; a generator of a plurality of road design scenarios using the underground layers; a selector of an optimal road design scenario out of the plurality of scenarios; a generator of drawings and specifications to implement the selected optimal road design scenario; and a calculator of quantities executed during the road construction project in order to monitor in real time the executed quantities and keep track of the progress in the execution of the road construction project.

The foregoing and other objects, advantages and features of the present invention will become more apparent upon reading of the following non-restrictive description of illustrative embodiments thereof, given by way of example only with reference to the accompanying drawings.

### BRIEF DESCRIPTION OF THE DRAWINGS

In the appended drawings:

FIG. 1 is a schematic block diagram of a computer system in which an embodiment of the method and system for designing, executing and managing road construction projects according to the present invention can be implemented;

FIG. 2 is a schematic diagram showing the various modules and sub-modules in an embodiment of the method and system for designing, executing and managing road construction projects according to the present invention;

FIG. 3 is a schematic diagram showing inputs, outputs and functionalities of a sub-module for creating and editing digital land models in the method and system for designing, executing and managing road construction projects as illustrated in FIG. 2;

FIG. 4 is a schematic diagram showing inputs, outputs and functionalities of a sub-module for drawing sketches in the method and system for designing, executing and managing road construction projects as illustrated in FIG. 2;

FIG. 5 is a schematic diagram showing inputs, outputs and functionalities of a sub-module for selecting initial data in the method and system for designing, executing and managing road construction projects as illustrated in FIG. 2;

FIG. 6 is a schematic diagram showing inputs, outputs and functionalities of a sub-module for creating and editing preliminary alignment in the method and system for designing, executing and managing road construction projects as illustrated in FIG. 2;

FIG. 7 is a schematic diagram showing inputs, outputs and functionalities of a sub-module for acquiring surveying data in the method and system for designing, executing and managing road construction projects as illustrated in FIG. 2;

FIG. 8 is a schematic diagram showing inputs, outputs and functionalities of a sub-module for generating ground surfaces in the method and system for designing, executing and managing road construction projects as illustrated in FIG. 2;

FIG. 9 is a schematic diagram showing inputs, outputs and functionalities of a sub-module for generating scenarios in the method and system for designing, executing and managing road construction projects as illustrated in FIG. 2;

FIG. 10 is a schematic diagram showing inputs, outputs and functionalities of a sub-module for creating and editing horizontal alignment in the method and system for designing, executing and managing road construction projects as illustrated in FIG. 2;

FIG. 11 is a schematic diagram showing inputs, outputs and functionalities of a sub-module for managing superelevation in the method and system for designing, executing and managing road construction projects as illustrated in FIG. 2;

FIG. 12 is a schematic diagram showing inputs, outputs and functionalities of a sub-module for creating and editing vertical profiles in the method and system for designing, executing and managing road construction projects as illustrated in FIG. 2;

FIG. 13 is a schematic diagram showing inputs, outputs and functionalities of a sub-module for creating and editing design surfaces in the method and system for designing, executing and managing road construction projects as illustrated in FIG. 2;

FIG. 14 is a schematic diagram showing inputs, outputs and functionalities of a sub-module for calculating theoretical quantities in the method and system for designing, executing and managing road construction projects as illustrated in FIG. 2;

FIG. 15 is a schematic diagram showing inputs, outputs and functionalities of a sub-module for defining a “right-of-way” database in the method and system for designing, executing and managing road construction projects as illustrated in FIG. 2;

FIG. 16 is a schematic diagram showing inputs, outputs and functionalities of a sub-module for validating design criteria in the method and system for designing, executing and managing road construction projects as illustrated in FIG. 2;

FIG. 17 is a schematic diagram showing inputs, outputs and functionalities of a sub-module for generating a final layout in the method and system for designing, executing and managing road construction projects as illustrated in FIG. 2; and

FIG. 18 is a schematic diagram showing inputs, outputs and functionalities of a sub-module for determining the executed quantities in the method and system for designing, executing and managing road construction projects as illustrated in FIG. 2.

### DETAILED DESCRIPTION

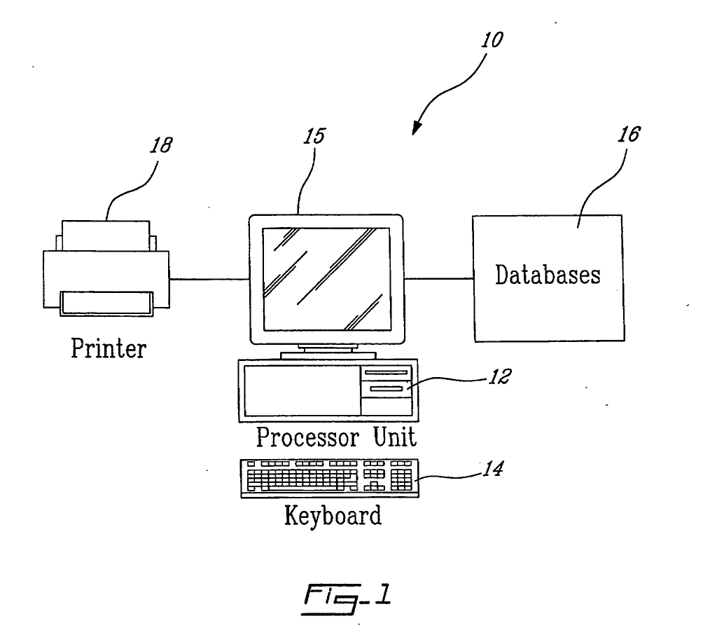

FIG. 1 shows a computer system 10 with which the method and system for designing, executing and managing road construction projects according to the present invention can be implemented. More specifically, the computer system 10 includes a processor unit 12 connected to a keyboard 14, a monitor 15 and a printer 18. The computer system 10 also comprises databases 16 for allowing the processor unit 12 to run processes and softwares.

FIG. 2 is a schematic diagram showing the various modules and operations of an embodiment of the method and system for designing, executing and managing road construction projects according to the present invention. The various modules and operations of the embodiment of the method and system for designing, executing and managing road construction projects according to the present invention are implemented in a single computer software.

More specifically, the method and system 30 as illustrated in FIG. 2 is divided into four (4) main modules 32, 34, 36 and 40.

Module 32

Module 32 puts together initial input data used in the process of designing the road construction project.

Module 34

Module 34 determines the underground layers that form the foundations, based on the input data provided from module 32.

Module 36

Once the underground layers have been determined, module 36 is concerned with the phase of design of the road. Module 36 is designed to generate a scenario of road construction project. Sub-module 38 performs a recursive loop; more specifically the operation performed by module 36 is repeated for generating a plurality of scenarios out of which an optimal scenario is selected.

Module 40

The function of module 40 is to produce drawings and specifications of the optimal scenario as selected by sub-module 38.

Once the operations performed by the module 40 have been completed, the drawings and specifications are ready to be contracted out and the road is ready to be constructed on site in accordance with the specifications established in module 40.

As illustrated in FIG. 2, the main modules 32, 34, 36 and 40 each comprise several sub-modules for achieving their respective tasks.

Module 32

More specifically, the first main module 32 comprises three sub-modules; a sub-module 42 for creating/editing a digital land model, a sub-module 44 for drawing a sketch, and a sub-module 46 for inputting other input initial data.

Sub-Module 42

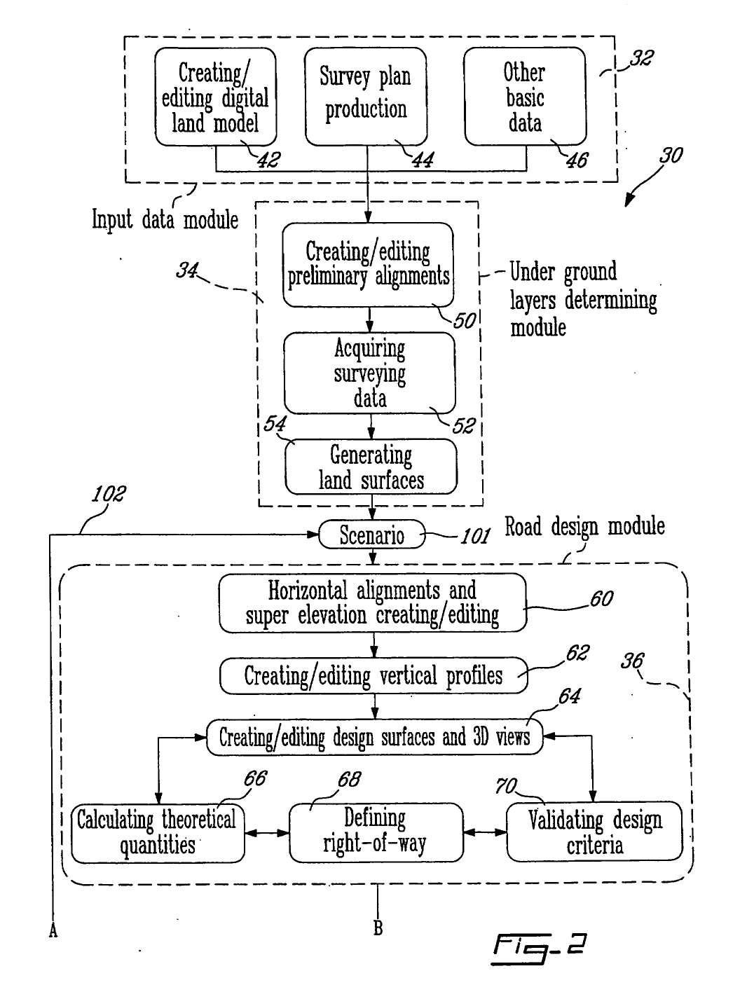

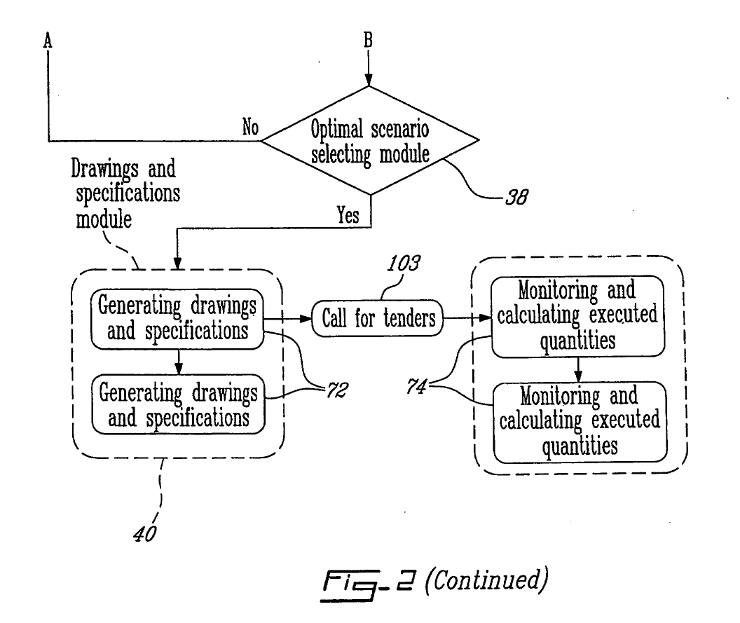

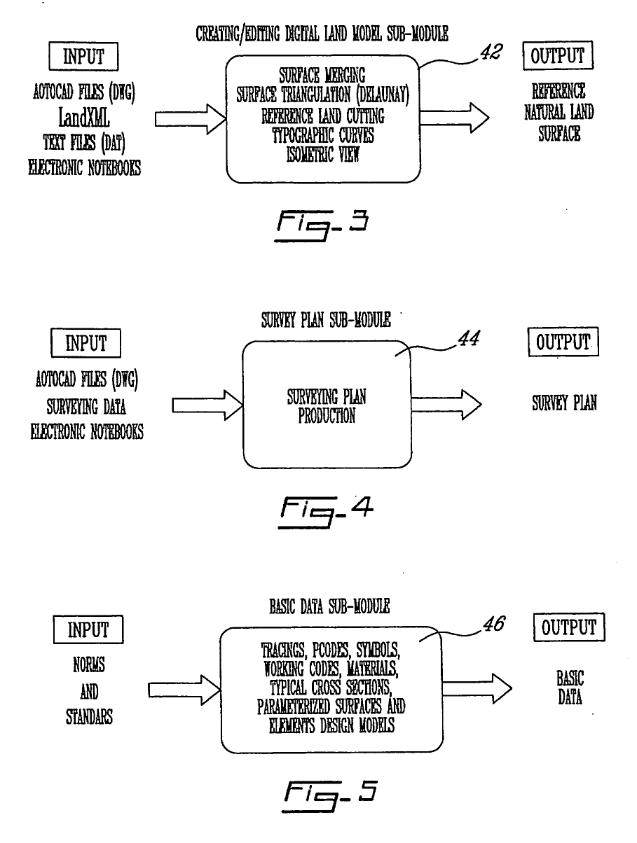

FIG. 3 illustrates a sub-module 42 of the input data module 32 of the method and system for designing, executing and managing road construction projects according to FIG. 2.

Referring to FIG. 3, the main objective of the sub-module 42 is to create/edit a digital land model. More specifically, the sub-module 42 generates an input reference natural land surface used for the rest of the design process. For that purpose, it is possible to build a land surface from scratch but in most of cases, land surfaces are already built and available from existing land surveying databases. These land surface data can be imported in the sub-module 42 in different formats such as AutoCad™ files (DWG), LandXML™, text files (DAT) and directly from electronic notebooks used in the fields. Sometimes, the land surface data come in batches and it is necessary to merge the batches together in order to generate a single surface representing the reference natural land surface. For the surfaces to be represented in space, they have first to be triangulated. Surface triangulation may be performed, for example, through the triangulation algorithm of Delaunay. To do so, an external border must be identified and interior lines or breaklines have also to be specified so that a surface corresponding properly to the real surface can be obtained. Furthermore, it is possible to cut out the reference land surface in order to create a significant corridor space. Indeed, the area demarcated by surveying data is sometimes very large. Thus, it is useful to reduce the workspace by keeping only the points located in the defined corridor space. Also, different display tools are available in order to show a preview of the generated surface(s). For example, topographic curves can be displayed and triangulated surfaces can be shown in three dimensions (3-D) via an isometric view.

To summarize, the sub-module 42 receives as inputs land surface data from AutoCAD files, LandXML, text files and/or electronic notebooks. Then the sub-module 42 performs the above-described tasks of surface merging, surface triangulation, surfaces cuttin, etc. in order to create a reference natural land surface as output.

Sub-Module 44

FIG. 4 illustrates a sub-module 44 for producing a survey plan forming part of the input data module 32 of the method and system for designing, executing and managing road construction projects according to FIG. 2.

A survey plan is a topographic drawing of the real land. The survey plan is used as a planning basis in different portions of a road construction project. Depending on the nature and extent of the road construction project, the survey plan can present planimetric and/or altimetric elements necessary to the decision-making process. Furthermore, the survey plan is used as an initial drawing reference in several portions of the software. The survey plan uses a system of x, y and z coordinates and is structured with a superposition of tracings. Each tracing is made of entities such as a single point, a polyline (a series of points joined together by lines), an image, a symbol (a gathering of entities), a text and an arc. The sub-module 44 offers a great flexibility in obtaining the survey plan. Indeed, a topographic drawing can be created with a suitable drawing tool included in the software of the method and system 30 for designing, executing and managing road construction projects or can be imported from a data file in different formats such as text, AutoCad, Vision Plus™ or from an electronic notebook. The imported data file can of course be subsequently modified. The drawing tool may comprise several functionalities, for example the creation of effects of closeness and distance through zooming. The user can measure distances and surfaces and can also add a new entity in different manners to other entities already appearing in the survey plan. The survey plan can be saved in the database of the software in several formats such as AutoCad format. It is also possible to export data from the survey plan to the drawings and specifications.

To summarize, as illustrated in FIG. 4, the sub-module 44 receives input data from AutoCAD files, surveying data and/or electronic notebook data and uses the received data to construct the survey plan.

Sub-Module 46

FIG. 5 illustrates a sub-module 46 of the input data module 32 of the method and system for designing, executing and managing road construction projects according to FIG. 2.

Referring to FIG. 5, the sub-module 46 is provided to receive other basic data for use by the designer as guidelines throughout the designing process of a road construction project. These basic data can be only changed by the system administrator, not by the end users. However, once these data are imported into a newly created road construction project, they become independent and can be modified at will according to the user's or designer's needs. The basic data are all included in one library. It is possible to define more than one library. Each library may contain a list of tracings, a list of Pcodes, a list of symbols, working codes, materials, typical cross sections, a list of parameterized surfaces, a list of parameterized elements and design models. All of these data are used later on to accelerate and guide the designing process.

To summarize, as illustrated in FIG. 5, the sub-module 46 receives as inputs road construction norms and standards and outputs basic data useful for the road design module 36.

Module 34

Once the input data have been received and/or generated by the input data module 32, these input data are used as input for the second module 34 for determining underground layers of the road construction project. As illustrated in FIG. 2, the module 34 comprises three sub-modules, a sub-module 50 for creating/editing preliminary alignments, a sub-module 52 for acquiring surveying data and a sub-module 54 for generating land surfaces.

Sub-Module 50

FIG. 6 illustrates the preliminary alignment creating/editing sub-module 50 of the underground layers determining module 34 of the method and system for designing, executing and managing road construction projects according to FIG. 2.

An objective of the sub-module 50 is to build a preliminary alignment which will be used thereafter during the definition of the underground layers and for the acquisition of surveying data. For example, a horizontal alignment of a road corresponds to a bird's eye view of the road alignment. An alignment is made from a 2 dimensional coordinate (x, y) system, comprising starting points, ending points, tangents, points of intersection and curves. Curves can be of two types: circular curves or spirals. An alignment can be created from scratch; however horizontal alignments are usually built based on the survey plan from sub-module 44. It is therefore possible to identify with precision some relevant elements of the survey plan. Also, the reference natural land surface from sub-module 44 can be used to guide building of the preliminary alignment. However, there already exists several data in Land XML or standand text formats which can be easily imported into the sub-module 50 for modification or to be used as is. There also exists several input data that can be used for correctly building an alignment. These input data can take various forms, for example the type of environment (rural or urban), the speed of design, the average daily output (YADO), etc. These data, combined with defined design standards, help the designer to create combinations of tangents, curves and spirals in agreement with the required safety rules (Curve-Curve (CC), Curve-Spiral (CS), Spiral-Curve (SC), etc). Alignment editing is initially carried out graphically, but can also be done in text mode for more precision. The editing process is provided with a complete system of constraints for assisting the designer in his work. Constraints are geometrical forms that restrict a movement. Constraints can be applied to individual tangents or to the whole alignment. For example, a constraint applied to a tangent can be a point constraint which limits the location of points where the tangent can be moved. Another example is the direction constraint, which forces the tangent to keep the same direction. Many other constraints, for example external and displacement constraints known to those of ordinary skill in the art can be applied. Finally, several related auxiliary tools are available to create preliminary alignments such as: tools to shift an alignment, to merge two alignments, to reverse an alignment, to shorten an alignment.

The sub-module 50 receives as input the reference natural land surface from sub-module 42, the survey plan from sub-module 44, LandXML and text files and other basic data from sub-module 46 in order to create a preliminary alignment as an output of the sub-module 50.

Sub-Module 52

FIG. 7 illustrates the surveying data acquiring sub-module 50 of the underground layers determining module 34 of the method and system for designing, executing and managing road construction projects according to FIG. 2.

The function of the sub-module 52 is to define underground surveys in order for the module 54 to generate underground surfaces as will be described hereinbelow. Surveys are generally defined in terms of sections according to the preliminary alignment and they are used to model the underground layers. For each survey, a series of materials with their respective thicknesses have first to be determined. Secondly, the transversal relations governing the materials have to be determined. Finally, the longitudinal relations between the surveying sections have to be defined.

The sub-module 52 receives as input the original land generated by sub-module 42, the preliminary alignment from sub-module 50, and some basic data regarding the materials from sub-module 46 in order to output surveying data, transversal relations and a longitudinal scheme, which are all used to obtain continuous underground layers over the entire workspace.

Sub-Module 54

FIG. 8 illustrates the land surfaces generating sub-module 54 of the underground layers determining module 34 of the method and system for designing, executing and managing road construction projects according to FIG. 2.

The function of the sub-module 54 is to generate triangulated land surfaces according to the reference natural land surface from sub-module 42, and the surveying data, transversal relations and longitudinal scheme from sub-module 52. A land surface is represented with a hierarchical list in a tree form and is considered as objects made with points, lines and results from triangulation.

The points related to the underground layers are interpolated in relation to the cross sections obtained during the surveys and their relations. The triangles of the underground layers situated at the boundaries of the work area are truncated and reorganized in order to respect these limits.

The sub-module 54 receives as inputs the reference natural land surface from sub-module 42, the surveying data, transversal relations and longitudinal scheme from sub-module 52 and then, generates the underground layers outputs the generated land surfaces which can be used by several other modules, as will be explained in the following description.

Module 36

Once the underground layers have been generated in module 34, the road design module 36 is used to design several scenarios of road projects until a final scenario, meeting all the requirements, is selected. Therefore, the road design module 36 is provided with an iterative loop, including road design module 36, optimal scenario selecting module 38, scenario sub-module 101 and loop 102, for generating scenarios until a final scenario is selected in optimal scenario selecting module 38.

The road design module 36 comprises six sub-modules, a sub-module 60 for creating/editing horizontal alignments and superelevation, a sub-module 62 for creating/editing vertical profiles, a sub-module 64 for creating/editing design surfaces and 3D views, a sub-module 66 for calculating theoretical quantities, a sub-module 68 for defining right-of-way and a sub-module 70 for validating the design criteria.

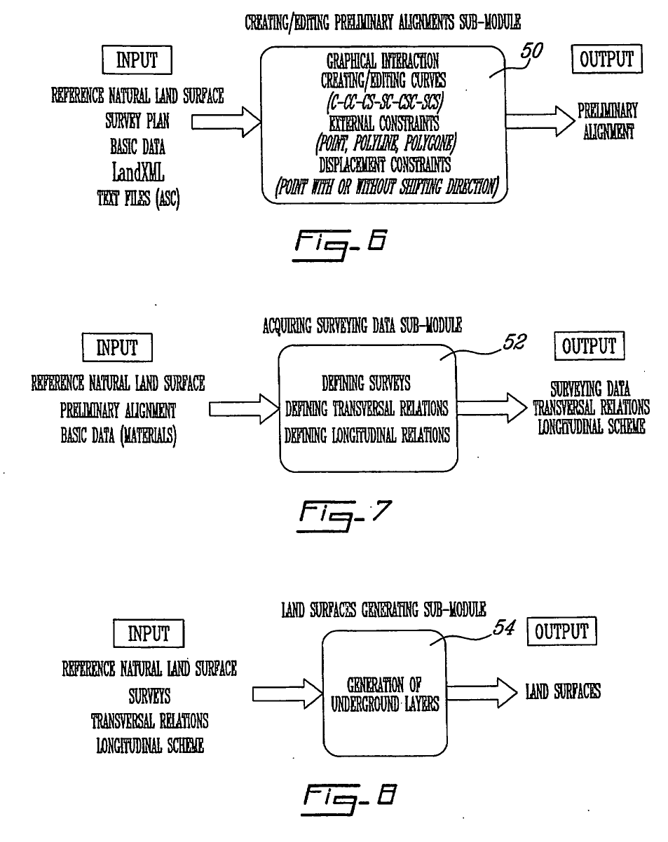

FIG. 9 illustrates the iterative loop for generating scenarios. This loop allows the designer to create several iterations for a given problem. Indeed, results for various scenarios can be calculated and thus the impact of one scenario over the others can be evaluated in order to choose an optimal scenario to be the final scenario. Each scenario with its specific data is completely independent from each other. A scenario is generated by the road design module 36 using results from the prior modules and sub-modules: the survey plan from sub-module 44, the preliminary alignment from sub-module 50, land surfaces from sub-module 54 and the basic data from sub-module 46. The orientation of a scenario is given by a main horizontal alignment and its associated vertical profile. Then, a set of superelevation, design surfaces and right-of-way are associated to this horizontal alignment. Moreover, the design procedure is based on design criteria such as the speed of design, the average daily output, etc. When the road is designed according to the rules of the art, the theoretical quantities involved in such a design can be calculated. Finally, after a comparison between all the generated scenarios, the optimal scenario is chosen by the optimal scenario selecting module using a value given by the theoretical quantities.

Sub-Module 60

FIG. 10 illustrates the sub-module 60 for creating/editing horizontal alignments and superelevation of the road design module 36 of the method and system for designing, executing and managing road construction projects according to FIG. 2.

The function of the sub-module 60 is to build the main horizontal alignment as well as secondary horizontal alignments, which will be used thereafter during creation/edition of the vertical profiles, management of the superelevation, creation/edition of design surfaces, definition of the right-of-way and finally during calculation of the theoretical quantities.

These alignments can be created from scratch. However, horizontal alignments are usually built based on the survey plan. That is why it is possible to identify with precision some relevant elements of the survey plan. Moreover, the reference natural land surface can be also used to guide the construction of the alignment. However, there already exists data in XML file format or in standard text files which can be easily imported in the module 60 for modification or usage as such.

In addition, there are several basic data for building proper alignments. These data can take various forms: type of environment (rural or urban), speed of design, daily average output (YADO), etc. These data, combined with predefined design standards, allow the designer to create combinations of tangents, curves and spirals in agreement with the required safety rules (Curve-Curve (DC), Curve-Spiral (CS), Spiral-Curve (SC), etc).

Alignment editing is essentially carried out graphically, but it can also be done in a text mode for more precision. The editing process is provided with a complete system of external (point, poly-line, polygon) and displacement (point with or without shift, direction) constraints for assisting the designer in his work.

Finally, several related auxiliary tools are available to create horizontal alignments such as: tools to shift an alignment, to merge two alignments, to reverse an alignment, to shorten an alignment, etc.

Therefore, the sub-module 60 receives as input the reference natural land surface from sub-module 42, the survey plan from sub-module 44, and the basic data from sub-module 46, LandXML, test files (ASC) to create a main alignment and secondary alignments which will be used in several subsequent modules and sub-modules as will be described hereinafter. A main alignment of a scenario can contain vertical profiles, design surfaces, superelevation and right-of-way, which is not the case for a secondary alignment.

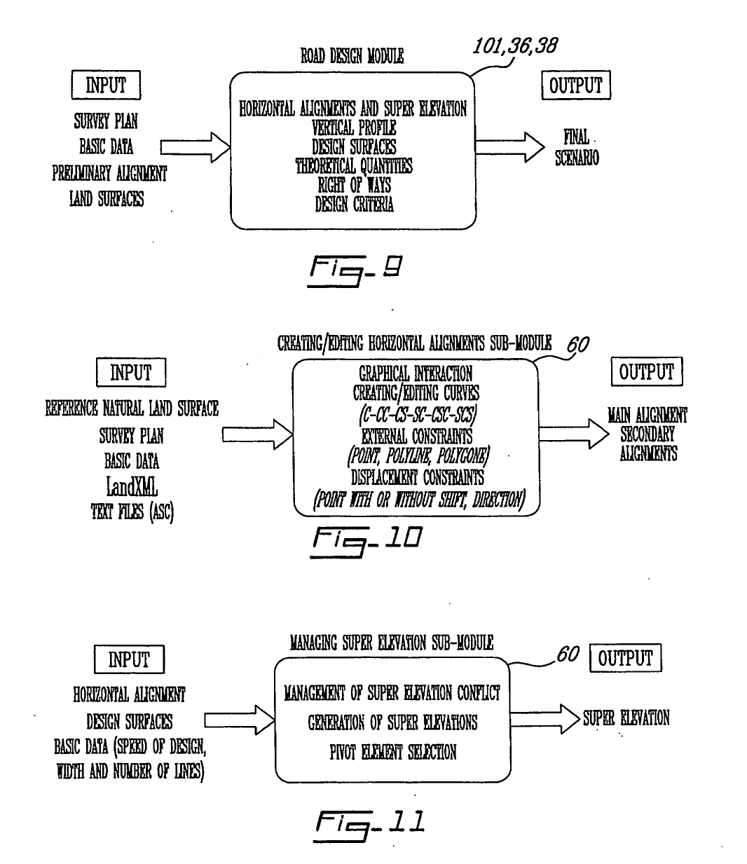

FIG. 11 illustrates a second portion of the sub-module 60 which is concerned with managing the superelevation. The function of the second portion of the sub-module 60 is to assist the designer during the management of the superelevation of the road curves. The management of the superelevation is carded out over two distinct portions of the road: the paving and the shoulder. Depending on different factors such as the speed of design and the radius of the involved curves, the sub-module 60 calculates the percentages of superelevation and the suitable slopes of transition. Whenever required, the sub-module 60 is able to manage superelevation conflicts by using various methods. For instance, when tangents between curves are short, transition zones can overlap each other. To solve this kind of conflicts, a window with many options is provided. The options consist, for example, of reducing a length of transition or eliminating transition zones. Finally, by using surfaces design, it is possible to select a pivot element different from the normally used central line.

To operate, the superelevation management portion of the sub-module 60 is used in relation to an horizontal alignment. Then, it is possible to apply superelevation(s) defined in sub-module 60 directly to the design surfaces.

The superelevation managing portion of the sub-module 60 receives as input a horizontal alignment from sub-module 60, design surfaces and basic data from sub-module 46 in order to produce a superelevation that can directly be related to design surfaces.

Sub-Module 62

FIG. 12 illustrates the sub-module 62 for creating/editing vertical profiles of the road design module 36 of the method and system for designing, executing and managing road construction projects according to FIG. 2.

The function of the sub-module 62 is to build the vertical profile associated with a horizontal alignment. The vertical profile combined with its horizontal alignment represent the center line of the road in three dimensions.

The vertical profile is similar to the horizontal alignment. It is represented in a two-dimensional system along axes x and z. The coordinate x corresponds to a chaining and the coordinate z to an elevation. Actually, the vertical profile corresponds to a side view of the horizontal alignment of the road. The vertical profile is made from elements such as points, tangents and curves. Each vertical profile has one starting point and one ending point. The curves are given by parabolas.

The vertical profile can be built on the basis of the land surfaces from sub-module 54, even though there already exists data for the vertical profiles under the form of LandXML files or standard text files (ASC). These files can be easily imported in the sub-module 62 in order to be modified or used as such.

In addition, there are several basic data used for building correctly a vertical profile. These basic data can take various forms: type of environment (rural or urban), speed of design, average daily output (YADO), etc. These basic data, combined with predefined standards of design allow the designer to create suitable parabolas in agreement with required safety and construction rules.

Vertical profile editing is essentially carried out graphically, but it can also be done in a text mode for more precision. Furthermore the whole editing process is strongly supported by a complete system of constraints for assisting the designer in his work. Constraints are geometrical forms that restrict a movement. Constraints can be applied to a tangent or the whole vertical profile. For example, constraints applied to a tangent comprise point constraints and direction constraints. Point constraints limit location points where a user can move the tangent. And direction constraints force a tangent to keep the same slope.

The sub-module 62 receives as input the horizontal alignment produced by sub-module 60, the land surfaces from sub-module 54, LandXML and text (ASC) files and produces as output a vertical profile.

Sub-Module 64

FIG. 13 illustrates the sub-module 64 for creating/editing design surfaces and 3D views of the road design module 36 of the method and system for designing, executing and managing road construction projects according to FIG. 2.

The function of the sub-module 64 is to define the structure of the roadway. But before doing that, typical basic road cross sections are chosen or created. After that, it will be possible to perform a projection of these road cross sections onto the associated horizontal alignment. The road cross sections are used to create a road structure to be replicated along a horizontal alignment and a vertical profile. Creating an road cross section comprises creating a road surface layer called template, and an underground structure holding the template. In addition, the road cross section is used to determine the elevation of design surfaces with respect to the center line. The editing process of design surfaces can be carried out about three view planes: cross section, elevation and plan. The editing process also enables graphical editing of various elements of the road. Design surfaces can attach precisely to any land surfaces, but in most of the cases the designer is interested in natural land and rock.

Many manipulations of the design surfaces are possible: add a new surface, merge two surfaces, copy or remove a surface. Also, a multitude of functionalities can be used to manipulate the elements of design surfaces. Superelevations can also interact and define design surfaces by applying appropriate slopes in the curves of the horizontal alignment.

The sub-module 64 receives as input the horizontal alignment from the sub-module 60, the vertical profile from the sub-module 62, the superelevation from the sub-module 60 and the land surfaces from the sub-module 54 in order to create design surfaces which will be used later on to calculate the theoretical quantities involved in such a road design.

Sub-Module 66

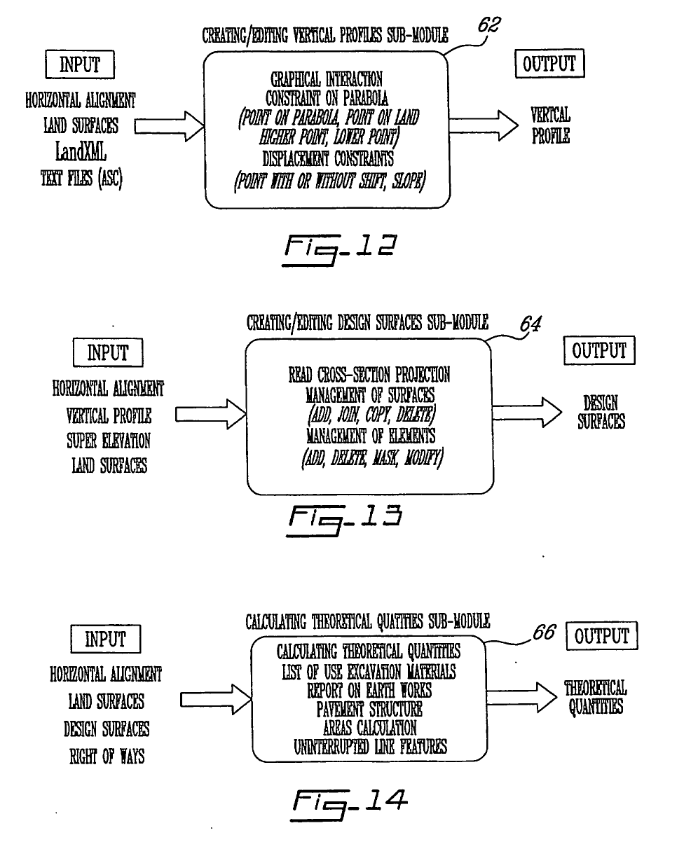

FIG. 14 illustrates the sub-module 66 for calculating theoretical quantities of the road design module 36 of the method and system for designing, executing and managing road construction projects according to FIG. 2.

The function of the sub-module 66 is to calculate the quantities of various materials involved in the design of a road project: excavation, embankment, structure of the roadway, areas and linear elements.

The theoretical quantities are calculated in relation to the axis of the horizontal alignment and in respect to the right-of-way. Calculation of quantities comprises determining quantities of excavated and filling materials, pavement structure, areas and uninterrupted line features. It is possible to generate several significant reports such as, for example, reports on areas calculations, on the pavement structure, etc. These reports can sometimes be edited and different factors (length, area, volume, factors of utilization and factor of filling in the report or use of the excavated materials, etc.) can be changed since they are set as modifiable parameters thus giving a great flexibility to the designer.

Finally, the theoretical quantities are used to determine the value of a scenario compared to another. Indeed, a deep analysis of the theoretical quantities can reveal a lot of information on the costs related to road construction and thus help the user to select a given, optimal scenario.

The sub-module 66 receives as input the horizontal alignment from sub-module 60, the land surfaces from sub-module 54, the design surfaces from sub-module 64 and the right-of-way to calculate the theoretical quantities.

Sub-Module 68

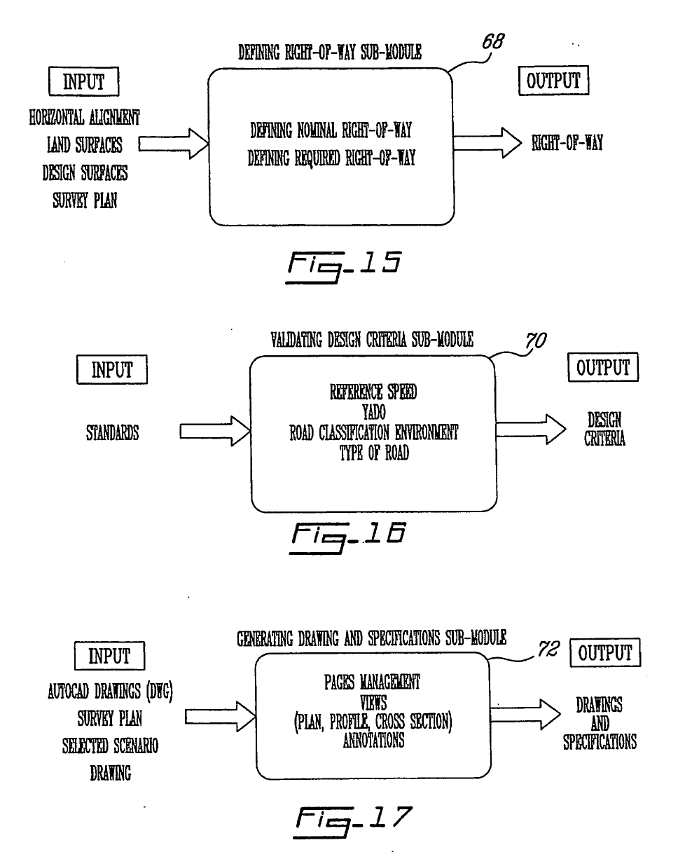

FIG. 15 illustrates the sub-module 68 for defining right-of-way of the road design module 36 of the method and system for designing, executing and managing road construction projects according to FIG. 2.

The right-of-way represents the work area related to the design of a road project, meaning that it gives the limits of the area that can be used for the construction of the new road. More specifically, the right-of-way determines the limits between public property and private property. The right-of-way also has a legal value. The right-of-way is defined as a function of the horizontal alignment, but is also based on the land surfaces and survey plan. The initial right-of-way is shown as a function of the structure of the pavement. This right-of-way represents usually the right-of-way in its raw state defined as a function of the chaining of the design surfaces. This initial right-of-way is thus very irregular. This is why a nominal right-of-way is defined in order to regularize the right-of-way that is required.

The sub-module 68 receives as input the horizontal alignment from sub-module 60, the land surfaces from sub-module 54, the design surfaces from sub-module 64 and the plan survey from sub-module 44 to define the right-of-way that is used to edit the design surfaces and the drawings.

Sub-Module 70

FIG. 16 illustrates the sub-module 70 for validating the design criteria of the road design module 36 of the method and system for designing, executing and managing road construction projects according to FIG. 2.

Basic data allow for checking whether certain standards of road design and construction have been met during various changes that can occur throughout the preparation of a project. These basic data include:

Reference speed: The reference speed corresponds to the speed of design. This criteria enables validation as to whether the horizontal alignment, the road cross sections and the superelevation meet with the different standards related to road design and construction.

YADO (Yearly Average Daily Output): YADO corresponds to the flow of road traffic per day in terms of vehicles. With YADO and the functional classification as defined hereinbelow of the projected road, it is possible to validate whether a template meets with the road cross sections as dictated by the standards of road design and construction.

Classification of the road: The roads are classified according to their function such as highway, main road, regional road, collector road or local road. With the functional classification of the road and the YADO, it is possible to validate whether a template meets with the road cross section of the established standards of road design and construction. The classification of the road also permits to determine whether the slopes of the road cross section meets with the standards.

Environment: The projected road is in rural or urban environments. Several standards apply to one or the other environment.

Type of roads: In rural environment, the road type (road cross section from TYPE A to TYPE F) results from the YADO and the functional classification of the projected road. These criteria are indicated on the standardized drawings (DN) I-5-001 to I-5-006. Other standardized drawings apply to roads with separate pavements in a rural environment with a YADO higher than 10000 vehicles per day and to roads in an urban environment. The standardized drawings will be provided during the design of a road construction project. With these data, it is possible to validate whether the template meets with the requirements of the road cross section according to the road design and constructions standards.

The sub-module 70 receives as input the standards and based on the different basic data, produces and outputs the design criteria.

Once the road design has been completed by the module 36, a corresponding scenario is generated. At this point, a recursive loop steps in (module 38, loop 102 and sub-module 101). Indeed, the road design is repeated by module 36 a desired number of times, determined by the user. When the desired number of scenarios has been obtained, comparison between each scenario is performed by module 38 to select the optimal one of these scenarios. As indicated in the foregoing description, a deep analysis of the theoretical quantities from sub-module 66 can reveal a lot of information on the costs related to road construction and thus help the user to select a given, optimal scenario. It is however within the scope of the present invention to use a number of other parameters and/or methods to select the optimal scenario.

Module 40

Once the final scenario from the road design module 36 has been selected and accepted, the last module 40 produces drawings and specifications corresponding to the selected, optimal scenario. Module 40 comprises a sub-module 72 for producing the drawings and specifications as a function of the optimal scenario selected by sub-module 38.

Sub-Module 72

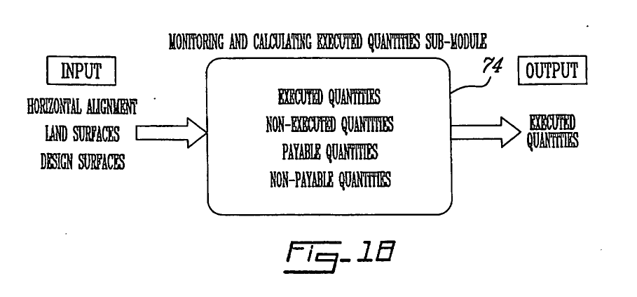

FIG. 17 illustrates the sub-module 72 for generating the drawings and specifications of the module 40 of the method and system for designing, executing and managing road construction projects according to FIG. 2.

One of the last steps of the road design is the preparation of the drawings and specifications. This step consists of generating the drawings and specifications in accordance with the selected scenario. The drawings and specifications contain the details of the work to be carried out in order to construct the road. It can be based on the survey plan or on an existing AutoCAD drawing. However, mechanisms are implemented so that the drawings and specifications can be only obtained from the selected optimal scenario.

The preparation of the drawings and specifications involves a complete system of management of pages and cartridges in order to facilitate the operations of the designer. It is also possible to parameterize the pages according to the requirements of the intended application by using a number of different views, for example, plan views, elevation views, cross sectional views, etc. Cartridges contain attributes (parametric information addressed to designers of the drawings and specifications) and recapitulating data concerning drawings found on the pages. Finally, several tools are implemented for allowing the addition of annotations.

The sub-module 72 receives as input AutoCAD drawings, the survey plan from sub-module 44, and the selected optimal scenario from sub-module 38 in order to generate the drawings and specifications related to this optimal scenario.

Once the drawings and specifications are contracted out through, for example, a call for tenders 103, the construction of the road according to the drawings and specifications may be undertaken. Once the construction begins, the executed quantities can be monitored and calculated by the sub-module 74.

Sub-Module 74

FIG. 18 illustrates the sub-module 74 for monitoring and calculating the executed quantities.

The objective of the sub-module 74 is to monitor and calculate the executed quantities of excavation and embankment which are really carried out on the site. By comparing them with the theoretical quantities calculated by sub-module 66, it is possible to detect differences between the theoretical quantities and the quantities really executed on the site. Indeed, the non executed quantities can be set apart from those which have been executed. Moreover, it is also possible to convert generally non-payable quantities into payable quantities for various reasons as defined by the involved parties. The executed quantities are calculated in relation to the axis of horizontal alignment. It is finally possible to generate reports exposing details related to the executed quantities which were calculated.

In this manner, the managers can monitor in real time the executed quantities to allow them to keep track of the progress in the execution of the road construction project. The managers accordingly detect immediately that the anticipated budget for the execution of the project is respected or exceeded.

Given the horizontal alignment from sub-module 60, the land surfaces from sub-module 54 and the design surfaces from sub-module 64, the sub-module 74 calculates the executed quantities.

Although the present invention has been described in the foregoing specification by means of a non-restrictive illustrative embodiment, this illustrative embodiment can be modified at will within the scope of the appended claims, without departing from the spirit and nature of the subject invention.

What is claimed is:

1. A method for executing and managing a road construction project, comprising the following operations implemented in a single computer software:
defining input data providing guidelines for designing the road construction project;
determining underground layers based on the input data;
generating a plurality of road design scenarios using the underground layers;
selecting an optimal road design scenario out of said plurality of scenarios;
producing drawings and specifications to implement the selected optimal road design scenario; and
calculating quantities executed during the road construction project in order to monitor in real time the executed quantities and keep track of the progress in the execution of the road construction project.

2. A method for executing and managing a road construction project according to claim 1, wherein generating a plurality of road design scenarios comprises, for each scenario, calculating a road design.

3. A method for executing and managing a road construction project according to claim 1, wherein generating a plurality of design scenarios comprises, for each road design scenario, calculating theoretical quantities of materials involved in the road design.

4. A method for executing and managing a road construction project according to claim 3, wherein the selection of an optimal road design scenario is conducted in relation to the theoretical quantities of materials involved in the road design.

5. A method for executing and managing a road construction project according to claim 1, wherein generating a plurality of road design scenarios comprises repeating a road design operation through a recursive loop.

6. A method for executing and managing a road construction project according to claim 1, wherein defining input data comprises producing a digital land model.

7. A method for executing and managing a road construction project according to claim 1, wherein defining input data comprises producing a survey plan.

8. A method for executing and managing a road construction project according to claim 1, wherein defining input data comprises defining basic data.

9. A method for executing and managing a road construction project according to claim 1, wherein determining underground layers comprises producing preliminary alignments.

10. A method for executing and managing a road construction project according to claim 9, wherein determining underground layers comprises acquiring surveying data using the preliminary alignments.

11. A method for executing and managing a road construction project according to claim 10, wherein determining underground layers comprises generating land surfaces using the acquired surveying data.

12. A method for executing and managing a road construction project according to claim 2, wherein calculating a road design comprises producing an horizontal alignment.

13. A method for executing and managing a road construction project according to claim 12, wherein calculating a road design comprises managing superelevation in relation to the horizontal alignment.

14. A method for executing and managing a road construction project according to claim 12, wherein calculating a road design comprises producing a vertical profile in relation to the horizontal alignment.

15. A method for executing and managing a road construction project according to claim 14 wherein calculating a road design comprises producing a design surface in relation to the horizontal alignment and vertical profile.

16. A method for executing and managing a road construction project according to claim 15, wherein calculating a road design comprises defining a right-of-way in relation to the horizontal alignment and the design surface.

17. A method for executing and managing a road construction project according to claim 16, wherein calculating a road design comprises calculating theoretical quantities of materials involved in the road design in relation to the horizontal alignment, the design surface and the right-of-way.

18. A method for executing and managing a road construction project according to claim 2, wherein calculating a road design comprises validating design criteria in order to meet with road design and construction standards.

19. A method for executing and managing a road construction project according to claim 1, wherein generating a plurality of road design scenarios comprises generating a given number of road design scenarios.

20. A system for executing and managing a road construction project, comprising, implemented in a single computer software:
a definer of input data providing guidelines for designing the road construction project;
a generator of underground layers based on the input data;
a generator of a plurality of road design scenarios using the underground layers;
a selector of an optimal road design scenario out of said plurality of scenarios;
a generator of drawings and specifications to implement the selected optimal road design scenario; and
a calculator of quantities executed during the road construction project in order to monitor in real time the executed quantities and keep track of the progress in the execution of the road construction project.

21. A system for executing and managing a road construction project according to claim 20, wherein the generator of a plurality of road design scenarios comprises, for each scenario, a calculator of a road design.

22. A system for executing and managing a road construction project according to claim 20, wherein the generator of a plurality of design scenarios comprises, for each road design scenario, a calculator of theoretical quantities of materials involved in the road design.

23. A system for executing and managing a road construction project according to claim 22, wherein the selector selects an optimal road design scenario in relation to the theoretical quantities of materials involved in the road design.

24. A system for executing and managing a road construction project according to claim 20, wherein the generator of a plurality of road design scenarios comprises a recursive loop for repeating a road design operation.

25. A system for executing and managing a road construction project according to claim 20, wherein the definer of input data comprises a producer of a digital land model.

26. A system for executing and managing a road construction project according to claim 20, wherein the definer of input data comprises a producer of a survey plan.

27. A system for executing and managing a road construction project according to claim 20, wherein the definer of input data comprises means for defining basic data.

28. A system for executing and managing a road construction project according to claim 20, wherein the generator of underground layers comprises a producer of preliminary alignments.

29. A system for executing and managing a road construction project according to claim 28, wherein the generator of underground layers comprises a sub-module that acquires surveying data using the preliminary alignments.

30. A system for executing and managing a road construction project according to claim 29, wherein the generator of underground layers comprises a sub-module that generates land surfaces using the acquired surveying data.

31. A system for executing and managing a road construction project according to claim 21, wherein the calculator of a road design comprises a producer of an horizontal alignment.

32. A system for executing and managing a road construction project according to claim 31, wherein the calculator of a road design comprises a manager of superelevation in relation to the horizontal alignment.

33. A system for executing and managing a road construction project according to claim 31, wherein the calculator of a road design comprises a producer of a vertical profile in relation to the horizontal alignment.

34. A system for executing and managing a road construction project according to claim 33, wherein the calculator of a road design comprises a producer of a design surface in relation to the horizontal alignment and vertical profile.

35. A system for executing and managing a road construction project according to claim 34, wherein the calculator of a road design comprises a definer of a right-of-way in relation to the horizontal alignment and the design surface.

36. A system for executing and managing a road construction project according to claim 35, wherein the calculator of a road design comprises a calculator of theoretical quantities of materials involved in the road design in relation to the horizontal alignment, the design surface and the right-of-way.

37. A system for executing and managing a road construction project according to claim 21, wherein the calculator of a road design comprises a sub-module that validates design criteria in order to meet with road design and construction standards.

38. A system for executing and managing a road construction project according to claim 20, wherein the generator of a plurality of road design scenarios generates a given number of road design scenarios.
